(19) United States
(12) Patent Application Publication
(10) Pub. No.: US 2025/0372431 A1
(43) Pub. Date: Dec. 4, 2025

(54) CENTERING DEVICE AND SUBSTRATE PROCESSING APPARATUS

(71) Applicant: SCREEN Holdings Co., Ltd., Kyoto (JP)

(72) Inventors: Itsuki KAJINO, Kyoto (JP); Hiroyuki UENO, Kyoto (JP); Kazuhiro SHOJI, Kyoto (JP); Ryotaro SHINOHARA, Kyoto (JP)

(21) Appl. No.: 19/214,261

(22) Filed: May 21, 2025

(30) Foreign Application Priority Data
May 28, 2024 (JP) 2024-086468

(51) Int. Cl. H01L 21/68; H01L 21/67; H01L 21/683

(52) U.S. Cl. CPC H01L 21/68; H01L 21/67023; H01L 21/6838

(57) ABSTRACT

A multi-mover provided in a centering device and a substrate processing apparatus moves a second contact member and a third contact member integrally in a first horizontal direction while the second contact member and the third contact member surround a center of a substrate holder together with a first contact member in a plan view vertically from above. The multi-mover includes: a multi-support configured to support the second contact member and the third contact member integrally; and a slide member mounted in a manner slidable in the first horizontal direction relative to a guide member fixedly arranged at a predetermined position while the slide member is coupled to the multi-support. The multi-support and the slide member are made of materials having respective coefficients of linear expansion with a difference dLE therebetween that fulfills the following inequality: dLE<AE/(0.8597×dTM).

### CROSS REFERENCE TO RELATED APPLICATION

The disclosure of Japanese Patent Application No. 2024-86468 filed on May 28, 2024 including specification, drawings and claims is incorporated herein by reference in its entirety.

### BACKGROUND OF THE INVENTION

### 1. Field of the Invention

This invention relates to a centering technique for aligning a center of a disk-like substrate with a center of a substrate holder while the substrate is placed on an upper surface of the substrate holder, and a substrate processing apparatus for performing a process on a substrate utilizing the centering technique. This process includes a bevel etching process.

### 2. Description of the Related Art

In a known substrate processing apparatus, a process such as a chemical liquid process or a cleaning process is performed by supplying a processing liquid to a peripheral edge part of a substrate such as a semiconductor wafer while rotating the substrate. In a device described in Japanese Patent Application Laid-Open No. 2023-114594, for example, a substrate is held under suction while being supported from below by a spin chuck (corresponding to an example of a “substrate holder” of the present invention). In this case, misalignment between a center of the spin chuck and a center of the substrate decreases processing quality. In response to this, the above-described apparatus is provided with a centering device.

The centering device is to perform a so-called centering process for reducing the amount of eccentricity of the substrate from the spin chuck. More specifically, this centering device surrounds the substrate placed on the upper surface of the substrate holder using three contact members. Of these contact members, a first contact member is separated from the center of the substrate holder by a reference distance longer than the radius of the substrate and movable in a first horizontal direction from a first reference position toward the center of the substrate holder in a horizontal plane. Meanwhile, the other contact members include a second contact member and a third contact member provided in the horizontal plane on an opposite side to the first contact member with respect to the center of the substrate holder, as will be described next. Specifically, the second contact member is deviated from a virtual line extending in the first horizontal direction from the center of the substrate holder, separated from the center of the substrate holder by the reference distance, and movable in a second horizontal direction different from a direction from a second reference position toward the center of the substrate holder and approaching the substrate. The third contact member is on an opposite side to the second contact member with respect to the virtual line, separated by the reference distance from the center of the substrate holder, and movable in a third horizontal direction different from a direction from a third reference position toward the center of the substrate holder and approaching the substrate. As a result of repeated fine movements of the three contact members, the contact members approach the substrate gradually while keeping respective distances from the center of the substrate holder to the contact members equal. During these approaching movements, the contact members successively come into contact with the substrate to move the substrate horizontally toward the center of the substrate holder. As a result, the center of the substrate is aligned with the center of the substrate holder at a moment when the substrate is sandwiched by the three contact members. In this way, the centering process is completed.

### SUMMARY OF THE INVENTION

In the above-described centering device, the position of the substrate in an X direction that is a horizontal direction and parallel to the first horizontal direction is determined by sandwiching the substrate using the first contact member, the second contact member, and the third contact member. Meanwhile, the position of the substrate in a Y direction that is a horizontal direction and perpendicular to the X direction parallel to the first horizontal direction is determined using the second contact member and the third contact member. As an example, if the center of the substrate deviates from the center of the substrate holder toward the Y2 direction described in Japanese Patent Application Laid-Open No. 2023-114594, the second contact member comes into contact with an end face of the substrate while the tiny movements are repeated. If the tiny movements are repeated further while the contact state is maintained, the substrate is displaced in such a manner as to shift the center of the substrate toward the Y1 direction. This eventually causes the third contact member to come into contact with the end face of the substrate. As a result of this behavior, centering is realized in the Y direction. Specifically, the center of the substrate in the Y direction is determined using a positional relationship between the second contact member and the third contact member in the horizontal plane.

Each of the second contact member and the third contact member is supported by a support member (corresponding to an example of a “multi-support member” of the present invention) finished into a substantially C-shape in a plan view from above to maintain the above-described positional relationship constantly. In some cases, however, if a temperature changes in a substrate processing apparatus where the centering device is installed, namely, if an ambient temperature around the centering device changes, this positional relationship is changed. This forms one of main factors for reduction in centering accuracy.

This invention has been made in view of the foregoing problem, and is intended to improve accuracy in centering of the substrate by suppressing influence by the change in the ambient temperature.

A first aspect of the invention is a centering device. The device comprises: a first contact member capable of contacting an end face of a disk-like substrate placed in a horizontal posture on an upper surface of a substrate holder; a single mover configured to move the first contact member in a first horizontal direction; a second contact member and a third contact member each capable of contacting the end face of the substrate from an opposite side to the first contact member across the substrate holder; a multi-mover configured to move the second contact member and the third contact member integrally in the first horizontal direction while the second contact member and the third contact member surround a center of the substrate holder together with the first contact member in a plan view vertically from above; and a controller configured to control the single mover and the multi-mover so as to determine the position of the substrate on the substrate holder in such a manner that the substrate is sandwiched by the first contact member, the second contact member, and the third contact member from the first horizontal direction and the center of the substrate is aligned with the center of the substrate holder, wherein the multi-mover includes: a multi-support configured to support the second contact member and the third contact member integrally; a guide member extended in the first horizontal direction; a slide member mounted in a manner slidable in the first horizontal direction relative to the guide member fixedly arranged at a predetermined position while the slide member is coupled to the multi-support; a driver configured to generate driving force for moving the multi-support in the first horizontal direction; and a power transmitter configured to transmit the driving force to the multi-support, and with the amount of eccentricity of the substrate from the substrate holder permitted for a degree of change dTM in an ambient temperature defined as a permissible eccentricity amount AE, the multi-support and the slide member are made of materials having respective coefficients of linear expansion with a difference dLE therebetween that fulfills an inequality as follows:

$$dLE < AE / ( 0.8597 \times dTM ) .$$

A first aspect of the invention is a centering device. The device comprises: a first contact member capable of contacting an end face of a disk-like substrate placed in a horizontal posture on an upper surface of a substrate holder; a single mover configured to move the first contact member in a first horizontal direction; a second contact member and a third contact member each capable of contacting the end face of the substrate from an opposite side to the first contact member across the substrate holder; a multi-mover configured to move the second contact member and the third contact member integrally in the first horizontal direction while the second contact member and the third contact member surround a center of the substrate holder together with the first contact member in a plan view vertically from above; and a controller configured to control the single mover and the multi-mover so as to determine the position of the substrate on the substrate holder in such a manner that the substrate is sandwiched by the first contact member, the second contact member, and the third contact member from the first horizontal direction and the center of the substrate is aligned with the center of the substrate holder, wherein the multi-mover includes: a multi-support configured to support the second contact member and the third contact member integrally; a guide member extended in the first horizontal direction; a slide member mounted in a manner slidable in the first horizontal direction relative to the guide member fixedly arranged at a predetermined position while the multi-support is stacked on and coupled to an upper surface of the slide member; a driver configured to generate driving force for moving the multi-support in the first horizontal direction; and a power transmitter configured to transmit the driving force to the multi-support, and the multi-support and the slide member each have a plane symmetrical shape with respect to a vertical virtual plane including the center of the substrate holder and parallel to the first horizontal direction.

A third aspect of the invention is a substrate processing apparatus. The apparatus comprises: a substrate holder having an upper surface for supporting a substrate in a horizontal posture; the above centering device; a suction unit configured to suck and hold the substrate on the substrate holder by exhausting air between the substrate positioned by the centering device and the substrate holder; a rotation driver configured to rotate the substrate holder sucking and holding the substrate about a center of the substrate holder; and a processing liquid supply mechanism configured to supply a processing liquid to a peripheral edge part of the substrate rotated about the center of the substrate holder integrally with the substrate holder.

According to the invention having the above-described configuration, like in the centering device described in Japanese Patent Application Laid-Open No. 2023-114594, the centering process on the substrate proceeds by sandwiching the substrate from the first horizontal direction using the first contact member, the second contact member, and the third contact member. In particular, the second contact member and the third contact member are arranged separately at the one end portion and the other end portion of the multi-support respectively and move integrally with the multi-support. This might cause deterioration of centering accuracy resulting from change in an ambient temperature around the centering device. In this regard, the present invention employs at least one of material selection for each of the multi-support and the slide member and finishing of each of the multi-support and the slide member into a shape plane symmetrical with respect to the vertical virtual plane (a sign VS in FIG. 4 described later). As a result, reduction in centering accuracy resulting from the above-described change in the ambient temperature is suppressed.

As described above, according to the present invention, it is possible to prevent reduction in accuracy in centering of the substrate by suppressing influence by the change in the ambient temperature.

All of a plurality of constituent elements of each aspect of the invention described above are not essential and some of the plurality of constituent elements can be appropriately changed, deleted, replaced by other new constituent elements or have limited contents partially deleted in order to solve some or all of the aforementioned problems or to achieve some or all of effects described in this specification. Further, some or all of technical features included in one aspect of the invention described above can be combined with some or all of technical features included in another aspect of the invention described above to obtain one independent form of the invention in order to solve some or all of the aforementioned problems or to achieve some or all of the effects described in this specification.

### BRIEF DESCRIPTION OF THE DRAWINGS

FIG. 1 is a plan view showing a schematic configuration of a first embodiment of a substrate processing apparatus according to the invention.

FIG. 2 briefly shows a configuration in a first embodiment of the substrate processing apparatus.

FIG. 3 is a perspective view showing the configurations of a substrate holder and a centering mechanism of the substrate processing apparatus.

FIG. 4 is a perspective view showing the configuration of the multi-mover forming one of principal structures of the centering mechanism.

FIG. 5 is a graph showing a variation in centering accuracy resulting from a temperature change of 1C in the ambient temperature around the centering mechanism.

FIG. 6 is a perspective view showing the configuration of a multi-mover provided to a second embodiment of the centering device according to the present invention.

FIG. 7 is a perspective view showing the configuration of a multi-mover provided to a third embodiment of the centering device according to the present invention.

### DETAILED DESCRIPTION OF THE PREFERRED EMBODIMENTS

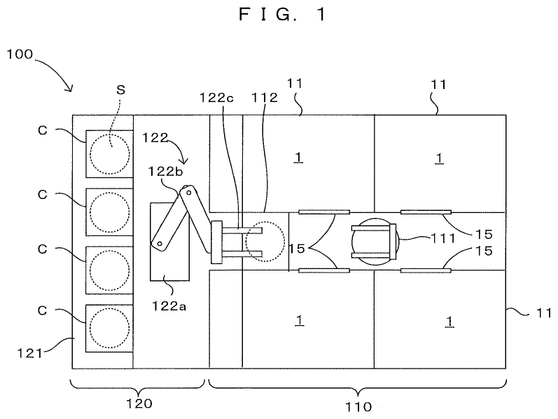

FIG. 1 is a plan view showing a schematic configuration of a first embodiment of a substrate processing apparatus according to the invention. This figure is a diagram not showing the external appearance of the apparatus, but showing an internal structure of a substrate processing system 100 by excluding an outer wall panel and other partial configurations. This substrate processing system 100 is, for example, a single-wafer type apparatus installed in a clean room and configured to process substrates W each having a circuit pattern (hereinafter, referred to as a “pattern”) only on one principal surface one by one. A substrate processing with processing fluid is carried out in a processing unit 1 equipped in the substrate processing system 100. In this specification, a pattern formation surface (one principal surface) formed with the pattern is referred to as a “front surface” and the other principal surface not formed with the pattern on an opposite side is referred to as a “back surface”. Further, a surface facing down is referred to as a “lower surface” and a surface facing up is referred to as an “upper surface”. Further, in this specification, the “pattern formation surface” means a surface of the substrate where an uneven pattern is formed in an arbitrary region regardless of whether the surface is flat, curved or uneven.

Here, various substrates such as semiconductor wafers, glass substrates for photomask, glass substrates for liquid crystal display, glass substrates for plasma display, substrates for FPD (Flat Panel Display), optical disk substrates, magnetic disk substrates and magneto-optical disk substrates can be applied as the “substrate” in this embodiment. Although the substrate processing apparatus used in processing semiconductor wafers is mainly described as an example with reference to the drawings below, application to the processing of various substrates illustrated above is also possible.

As shown in FIG. 1, the substrate processing system 100 includes a substrate processing area 110 for processing the substrate S of a circular plate shape. An indexer station 120 is provided adjacent to this this substrate processing area 110. The indexer station 120 includes a container holder 121 capable of holding a plurality of containers C for housing the substrates W (FOUPs (Front Opening Unified Pods), SMIF (Standard Mechanical Interface) pods, OCs (Open Cassettes) for housing a plurality of the substrates W in a sealed state), and an indexer robot 122 for taking out an unprocessed substrate S from the container C by accessing the container C held by the container holder 121 and housing a processed substrate S in the container C. A plurality of the substrates W are housed substantially in a horizontal posture in each container C.

The indexer robot 122 includes a base 122a fixed to an apparatus housing, an articulated arm 122b provided rotatably about a vertical axis with respect to the base 122a, and a hand 122c mounted on the tip of the articulated arm 122b. The hand 122c is structured such that the substrate S can be placed and held on the upper surface thereof. Such an indexer robot including the articulated arm and the hand for holding the substrate is not described in detail since being known.

In the substrate processing area 110, a mounting table 112 is provided to place a substrate S from the indexer robot 122. Also, in a plan view, a substrate transfer robot 111 is positioned almost in the center of the substrate processing area 110. Furthermore, a plurality of processing units 1 are arranged to surround this substrate conveyor robot 111. The substrate conveyor robot 111 randomly accesses the mounting table 112 and transfers the substrate W to and from the mounting table 112. The substrate conveyor robot 111 randomly accesses these processing units 1 and transfers the substrates W. On the other hand, each processing unit 1 performs a predetermined processing to the substrate S. In this embodiment, these processing units 1 have the same function. Thus, a plurality of the substrates W can be processed in parallel. In the embodiment, one of the processing units 1 corresponds to the substrate processing apparatus 10 according to the invention. If the substrate conveyor robot 111 can directly transfer the substrate W from the indexer robot 122, the mounting table 112 is not necessarily required.

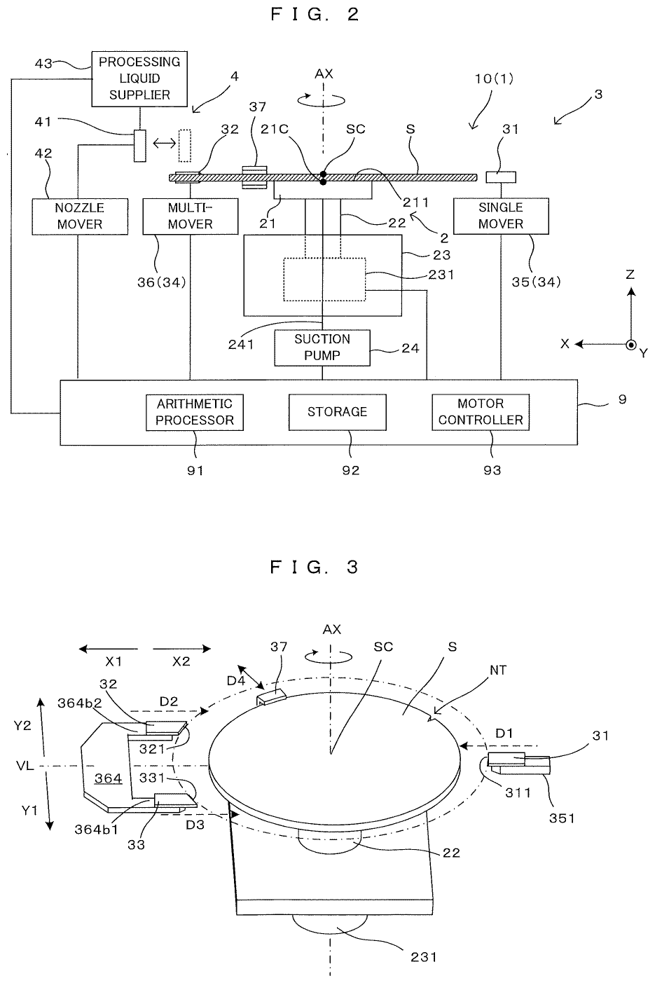

FIG. 2 briefly shows a configuration in a first embodiment of the substrate processing apparatus. FIG. 3 is a partial perspective view showing the configurations of a substrate holder and a centering mechanism of the substrate processing apparatus. The substrate processing apparatus 10 is an apparatus that performs a bevel etching process as an example of a “process” of the present invention, and supplies a processing liquid to a peripheral edge part of an upper surface of the substrate S in a processing chamber. For this purpose, the substrate processing apparatus 10 includes a substrate holder 2, a centering mechanism 3 forming a principal structure of a centering device according to the present invention, and a processing liquid supply mechanism 4. Operations of these structures are controlled by a controller 9 responsible for control over the apparatus entirely.

The substrate holder 2 includes a spin base 21 that is a member of a smaller circular plate shape than the substrate S. The spin base 21 is supported on a rotary support shaft 22 extending downward from a central part of a lower surface of the spin base 21 in such a manner as to locate an upper surface 211 of the spin base 21 horizontally. The rotary support shaft 22 is rotatably supported by a rotary driver 23. The rotary driver 23 includes a built-in rotary motor 231. The rotary motor 231 rotates in response to a control command from the controller 9. In response to receipt of resultant rotary driving force, the spin base 21 rotates about a vertical axis AX (alternate long and short dashed lines) extending in a vertical direction while passing through a center 21C of the spin base 21. In FIG. 2, a top-bottom direction corresponds to the vertical direction. A plane perpendicular to the plane of paper of FIG. 2 is a horizontal plane. To clearly show a relationship in terms of direction, a coordinate system defining a Z axis as the vertical direction and an XY plane as the horizontal plane is given in FIG. 2 and its subsequent drawings, if appropriate.

The upper surface 211 of the spin base 21 has a dimension by which the substrate S is supportable to allow the substrate S to be placed on the upper surface 211 of the spin base 21. Although not shown in the drawings, the upper surface 211 is provided with a plurality of suction holes or suction grooves, for example. Such suction holes or grooves are connected to a suction pump 24 through a suction pipe 241. This suction pump 24 serves as an example of the “suction unit” of the invention. In response to a control command from the controller 9, the suction pump 24 operates to apply suction power from the suction pump 24 to the spin base 21. As a result, air is exhausted from between the upper surface 211 of the spin base 21 and a lower surface of the substrate S, thereby holding the substrate S under suction on the spin base 21. Together with the rotation of the spin base 21, the substrate S held under suction in this way rotates about the vertical axis AX. Hence, the occurrence of misalignment between a center SC of the substrate S and the center 21C of the spin base 21, namely, decentering of the substrate S reduces the quality of the bevel etching process

In response to this, the centering mechanism 3 is provided in the present embodiment. The centering mechanism 3 works in conjunction with the controller 9 to function as a “centering device” according to the present invention. The centering mechanism 3 includes a measuring unit 37 for measuring a peripheral edge part of the substrate S held under suction by the spin base 21. As shown in FIG. 3, the measuring unit 37 is capable of acquiring peripheral edge information about the peripheral edge part of the substrate S by being located at the peripheral edge part of the substrate S held under suction by the spin base 21. In a radial direction D4 of the spin base 21, the measuring unit 37 is movable to a retreat position separated from the peripheral edge part of the substrate S. The measuring unit 37 used herein may be an edge detection sensor described in Japanese Patent Application Laid-Open No. 2021-54562, for example. More specifically, while the substrate S makes at least one rotation about the vertical axis AX together with rotation of the spin base 21, the measuring unit 37 detects an edge position of the substrate S in the radial direction of the spin base 21 and outputs an edge detection signal indicating the detected edge position to the controller 9 as the peripheral edge information. Thus, by analyzing the edge detection signal, it becomes possible to determine the amount of eccentricity of the center SC of the substrate S from the center 21C of the spin base 21 in each of an X direction a Y direction. Instead of the edge detection sensor, an imaging unit to capture an image of the peripheral edge part of the substrate S may be used as the measuring unit 37. In this case, successive images correspond to the peripheral edge information that are captured by the imaging unit while the substrate S makes at least one rotation about the vertical axis AX together with rotation of the spin base 21. A method of deriving an eccentricity amount in each of the X direction and the Y direction based on the edge detection signal or the successive images about the peripheral edge part is well known as described above, so that it is not described in detail herein.

The spin base 21 rotates while holding the substrate S under suction. When suction using the suction pump 24 is stopped, the substrate S becomes horizontally movable on the upper surface 211 of the spin base 21. A centering process is performed in this state. As a result of implementation of the centering process, the above-described eccentricity is eliminated to make alignment between the center SC of the substrate S and the center 21C of the spin base 21. The basic motion of the centering mechanism 3 including the above-described posture adjustment is the same as that of the device described in Japanese Patent Application Laid-Open No. 2023-114594. If an eccentricity amount exceeds a permissible value even after implementation of the centering process, a reference position is adjusted. This adjustment is also made in the same way as that of device described in Japanese Patent Application Laid-Open No. 2023-114594. Meanwhile, in the present embodiment, for the purpose of suppressing reduction in centering accuracy resulting from change in an ambient temperature around the centering mechanism 3, the configuration of the centering mechanism 3 partially differs from that of the device described in Japanese Patent Application Laid-Open No. 2023-114594. This will be described later in detail.

The processing liquid supply mechanism 4 is provided to perform the bevel etching process on the substrate S after implementation of the centering operation on the substrate S. The processing liquid supply mechanism 4 includes a processing liquid nozzle 41, a nozzle mover 42 that moves the processing liquid nozzle 41, and a processing liquid supplier 43 that supplies a processing liquid to the processing liquid nozzle 41. The nozzle mover 42 moves the processing liquid nozzle 41 between a retreat position and a processing position. The retreat position is the position evacuated from above the substrate S to the side, as shown by the solid line in FIG. 2. The processing position is above the periphery of the substrate S, as shown by the dotted line in FIG. 2.

The processing liquid nozzle 41 is connected to the processing liquid supplier 43. When a suitable processing liquid is supplied from the processing liquid supplier 43 to the processing liquid nozzle 41 located at the processing position, the processing liquid is ejected from the processing liquid nozzle 41 onto a peripheral edge part of the rotating substrate S. By doing so, the bevel etching process with the processing liquid is performed on the entire peripheral edge part of the substrate S.

Although not shown in FIG. 2, a splash guard is provided in such a manner as to surround the substrate holder 2 from the side. The splash guard collects droplets of a processing liquid blown off from the substrate S during implementation of the bevel etching process to effectively prevent the collected droplets from flying around the apparatus.

The configuration of the centering mechanism 3 will be described next by referring to FIGS. 2 to 5. The centering mechanism 3 has the function of determining the position of the substrate S by moving the substrate S horizontally on the upper surface 211 of the spin base 21 in such a manner as to align the center SC of the substrate S placed on the upper surface 211 of the spin base 21 with the center 21C of the spin base 21. As shown in FIG. 3, as viewed in the X direction, the centering mechanism 3 includes a contact member 31 arranged closer to an X2 direction (right-hand direction in FIG. 3) and a contact member 32 and a contact member 33 arranged closer to an X1 direction (left-hand direction in FIG. 3) with respect to the center 21C of the spin base 21. The centering mechanism 3 further includes a moving mechanism 34 for moving the contact members 31 to 33 in a horizontal direction.

The moving mechanism 34 includes a single mover 35 for moving the contact member 31, and a multi-mover 36 for moving the contact members 32 and 33 collectively. The single mover 35 is arranged closer to the X2 direction and the multi-mover 36 is arranged closer to the X1 direction with respect to the center 21C of the spin base 21. The single mover 35 and the multi-mover 36 only differ from each other in the shape and size of a support member for supporting the contact member and are basically the same in terms of the other configuration. Thus, in the following, the configuration of the multi-mover 36 directly relating to the technical problem of the present invention will be described mainly while the configuration of the single mover 35 will be described only briefly.

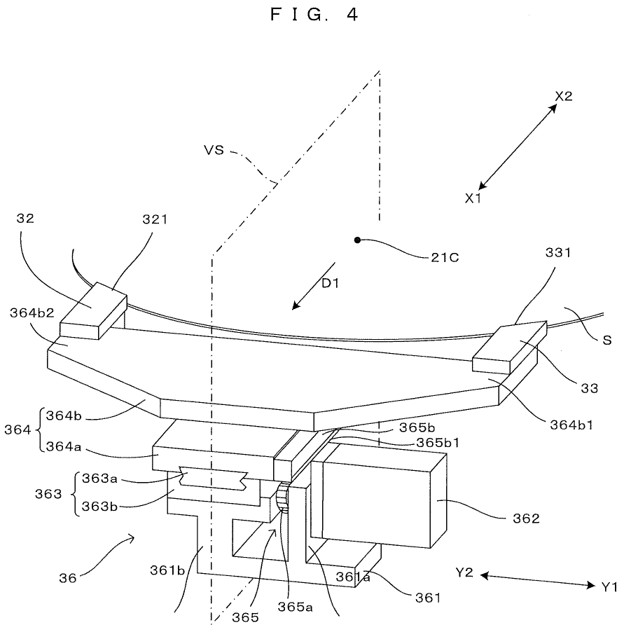

FIG. 4 is a perspective view showing the configuration of the multi-mover forming one of principal structures of the centering mechanism. The multi-mover 36 includes a base member 361 fixed to a frame (not shown in the drawings) of the substrate processing apparatus 10. The base member 361 includes a motor base part 361a and a linear guide base part 361b. The motor base part 361a is mounted with a motor 362 in such a posture that a rotary shaft thereof faces the linear guide base part 361b. The linear guide base part 361b is mounted with a linear guide 363 such as an LM guide (registered trademark). The linear guide 363 includes a rail 363a extended in the X direction, and a block 363b provided in a manner slidable in the X direction along the rail 363a relative to the rail 363a. In the present embodiment, the block 363b is fixed to a predetermined position at an upper surface of the linear guide base part 361b with a fastening fitting such as a bolt. Meanwhile, the rail 363a is provided over the block 363b in such a manner as to be movable back and forth in the X direction relative to the block 363b. Namely, in the present embodiment, the rail 363a and the block 363b correspond to an example of a “slide member” and a “guide member” of the present invention respectively. A relationship between the rail 363a and the block 363b can certainly be reversed. Specifically, in one configuration, the linear guide base part 361b may be finished into a shape extended in the X direction, the rail 363a may be fixedly arranged on an upper surface of the linear guide base part 361b, and the block 363b may be movable back and forth in the X direction relative to the rail 363a. In this case, the rail 363a and the block 363b correspond to an example of the “guide member” and the “slide member” of the present invention respectively.

As shown in FIG. 4, in the first embodiment, the rail 363a functioning as the slide member is mounted with a multi-support 364. The multi-support 364 includes a slide base 364a stacked on and fixed to an upper surface of the rail 363a, and a multi-support member 364b stacked on and fixed to the slide base 364a. In the present embodiment, the slide base 364a and the multi-support member 364b are independent plate members having the same composition, and form the multi-support 364 by being coupled to each other. In another case, a compact composed of the integrally-formed slide base 364a and multi-support member 364b can certainly be used as the multi-support 364. In another case, the multi-support 364 may be composed only of the multi-support member 364b. In this case, the multi-support member 364b is mounted directly on the rail 363a.

Like in the device described in Japanese Patent Application Laid-Open No. 2023-114594, the multi-support member 364b is finished into a substantially C-shape in a plan view from above. The multi-support member 364b has an end portion 364b2 closer to the Y2 direction on which the second contact member 32 is mounted in such a posture that a contact surface 321 thereof faces the substrate S on the spin base 21. The multi-support member 364b has an end portion 364b1 closer to the Y1 direction on which the third contact member 33 is mounted in such a posture that a contact surface 331 thereof faces the substrate S on the spin base 21. When driving force generated by the motor 362 is applied to the multi-support 364 through a power transmitter 365 as described next, the second contact member 32 and the third contact member 33 move in the X direction integrally with the multi-support 364.

As shown in FIG. 4, the power transmitter 365 includes a pinion gear 365a mounted on the rotary shaft of the motor 362, and a rack gear 365b capable of forming meshing engagement with the pinion gear 365a. The rack gear 365b is mounted on the multi-support 364 in such a posture that a teeth part 365b1 aligned in the X direction faces the pinion gear 365a and in such a state that the teeth part 365b1 is in meshing engagement with the pinion gear 365a. Thus, when the motor 362 operates in response to a rotation command from a motor controller 93 provided to the controller 9 responsible for control over the apparatus entirely, driving force generated by the motor 362 is transmitted to the multi-support 364 through the pinion gear 365a and the rack gear 365b. As a result, in response to the movement of the multi-support 364 in the X2 direction, the second contact member 32 and the third contact member 33 move in a D2 direction and a D3 direction respectively.

As is clear from FIG. 3, like in the device described in Japanese Patent Application Laid-Open No. 2023-114594, the single mover 35 includes a single support 351 finished into a substantially I-shape in a plan view from above. The single support 351 has an end portion closer to the X1 direction on which the first contact member 31 is mounted in such a posture that a contact surface 311 thereof faces the substrate S on the spin base 21. While not shown in the drawings, like the multi-mover 36, the single mover 35 includes a base member, a motor, a linear guide, and a power transmitter for moving the single support 351 in the X direction. Thus, when the motor of the single mover 35 operates in response to a rotation command from the motor controller 93, driving force generated by the motor is transmitted to the single support 351. As a result, in response to the movement of the single support 351 in the X1 direction, the first contact member 31 moves in a D1 direction.

The single mover 35 and the multi-mover 36 having the above-described configurations are controlled by the controller 9 to sandwich the substrate S using the three contact members 31 to 33, thereby performing the centering process like in the device described in Japanese Patent Application Laid-Open No. 2023-114594. The controller 9 includes an arithmetic processor 91 composed of a computer with a central processing unit (CPU), a random access memory (RAM), etc., a storage 92 such as a hard disk drive, and the motor controller 93. The controller 9 performs a bevel etching process in addition to the centering process described above.

The arithmetic processor 91 reads a centering program, a bevel etching program, etc. as appropriate stored in advance in the storage 92, develops the programs in the RAM (not shown in the drawings), and performs the centering process and the bevel etching process. In particular, like in the device described in Japanese Patent Application Laid-Open No. 2023-114594, the arithmetic processor 91 controls the single mover 35 and the multi-mover 36 in performing the centering process. More specifically, the first contact member 31 is caused to make a fine movement by the first single mover 35 and the second contact member 32 and the third contact member 33 are caused to make fine movements by the multi-mover 36 in such a manner that distances of the first contact member 31, the second contact member 32, and the third contact member 33 from the center 21C of the spin base 21 are kept equal. These fine movements are repeated until the first contact member 31, the second contact member 32, and the third contact member 33 have finished forming contacts with the substrate S entirely.

The arithmetic processor 91 calculates a load torque at the single mover 35 on the basis of a motor current value applied to the motor (not shown in the drawings) provided at the single mover 35 and calculates a load torque at the multi-mover 36 on the basis of a motor current value applied to the motor 362 (FIG. 4). The load torques vary in response to change in a distance from the center 21C of the spin base 21 to each of the contact surfaces 311, 321, and 331 (a distance from the base center to the contact surface) while the tiny movements are repeated. At a time when this distance conforms to the radius of the substrate S, specifically, when the substrate S is sandwiched by the contact members 31 to 33, the load torques increase steeply at the single mover 35 and the multi-mover 36 nearly simultaneously. Then, at a time when the load torque exceeds a threshold, the arithmetic processor 91 determines that the centering process is completed and stops the movements of the contact members 31 to 33.

The centering mechanism 3 determines the position of the substrate S on the spin base 21 in such a manner that the substrate S is sandwiched by the contact members 31 to 33 in the X direction and the center SC of the substrate S is aligned with the center 21C of the spin base 21. In order to perform such a centering process stably inside the substrate processing apparatus 10, namely, to maintain excellent centering accuracy even on the occurrence of change in an ambient temperature around the centering mechanism 3, verification was conducted on the configuration of each structure, arrangement thereof, etc. of the centering mechanism 3. As a result, the present inventors have found that, in order to suppress influence on centering accuracy caused by the change in the ambient temperature described above, it is important for the multi-mover 36 to fulfill at least one of a material selection requirement and a symmetrical shape requirement described next in detail.

The material selection requirement means selecting constituent materials for the multi-support 364 and the rail 363a in such a manner that a difference between a coefficient of linear expansion of the multi-support 364 and a coefficient of linear expansion of the rail 363a (slide member) becomes equal to or less than a certain value. The multi-support 364 and the rail 363a tightly contact each other. Hence, if the multi-support 364 and the rail 363a are made of different materials, a bimetallic phenomenon occurring in response to change in the ambient temperature may cause warpage of a body composed of the tightly-contacting multi-support 364 and rail 363a. As the warpage develops to a larger degree, the amount of displacement of each of the second contact member 32 and the third contact member 33 from a preset position becomes larger. As a result, a variation from a target centering position is increased and this may cause deterioration of centering accuracy.

The present inventors measured a variation in a centering position resulting from each temperature change of 1° C. in each of a case A and a case B described next. Then, the present inventors plotted a graph showing results of these measurements and result of a case C (a variation is zero) where coefficient of linear expansions are equal and no warpage occurs.

### <Case A>

An LM guide (coefficient of linear expansion: 12×10⁶/° C.) was used as the linear guide 363 composed of the rail 363a and the block 363b, and the multi-support 364 was prepared using aluminum (coefficient of linear expansion: 23.5×10⁶/° C.). In this case, with a difference dLE between the coefficients of linear expansion of 11.5×10⁶/° C., an observed variation in the centering position resulting from each temperature change of 1° C. was 10.545 μm.

### <Case B>

An LM guide (coefficient of linear expansion: 12×10⁶/° C.) was used as the linear guide 363 composed of the rail 363a and the block 363b, and the multi-support 364 was prepared using SUS304 (stainless steel, coefficient of linear expansion: 17.3×10⁶/° C.). In this case, with the difference dLE between the coefficients of linear expansion of 5.3×10⁶/° C., an observed variation in the centering position resulting from each temperature change of 1° C. was 3.636 μm.

### <Case C>

An LM guide (coefficient of linear expansion: 12×10⁶/° C.) was used as the linear guide 363 composed of the rail 363a and the block 363b, and the multi-support 364 was prepared using a material having the same coefficient of linear expansion as the LM guide. In this case, with the difference dLE between coefficients of linear expansion of zero, a variation in the centering position resulting from each temperature change of 1° C. is, in principle, zero.

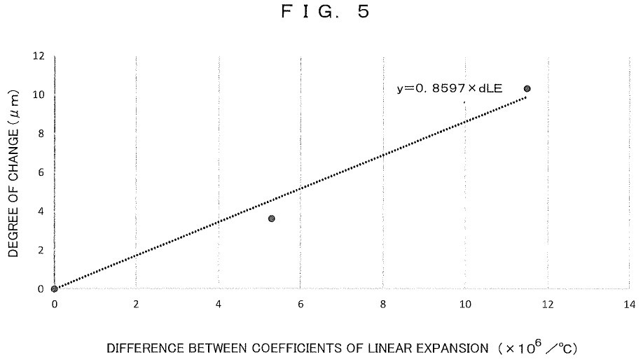

FIG. 5 is a graph showing a variation in centering accuracy resulting from a temperature change of 1° C. in the ambient temperature around the centering mechanism. A linear function indicating a variation in the centering position relative to the difference dLE between coefficients of linear expansion was derived as follows using three points in the graph:

$$y = 0.85 \; 97 \times dLE . \qquad Formula ( 1 )$$

Specifically, if the ambient temperature around the centering mechanism 3 arranged inside the substrate processing apparatus 10 changes by a degree of change dTM, a variation in the centering position resulting from a difference between coefficients of linear expansion (deterioration of centering accuracy) is determined as follows:

$$( a variation in the centering position ) = 0.8597 \times dLE \times dTM . \qquad Formula ( 2 )$$

Here, with an eccentricity amount (a variation in the centering position) permitted for the degree of change dTM in the ambient temperature defined as a permissible eccentricity amount AE, it becomes possible to suppress deterioration of centering accuracy caused by a bimetallic phenomenon within a range of the permissible eccentricity amount AE by fulfilling an inequality as follows:

$$AE > 0.8597 \times dLE \times dTM . \qquad Formula ( 3 )$$

Thus, it is preferable to form the multi-support 364 and the rail 363a (slide member) by using materials having respective coefficients of linear expansion with the difference dLE therebetween that fulfills an inequality as follows:

$$dLE < AE / ( 0.8597 \times dTM ) . \qquad Formula ( 4 )$$

If centering accuracy is required to be controlled to be equal to or less than 20 μm in a situation where the degree of change dTM in the ambient temperature is 10° C., for example, materials may be selected in such a manner that the difference dLE between coefficients of linear expansion becomes equal to or less than 2.326×10⁶/° C.

Here, the linear guide 363 and the multi-support 364 are ideally made of the same material in order to make the difference dLE between coefficients of linear expansion zero. If different materials are to be used for forming the linear guide 363 and the multi-support 364, however, these materials are desirably selected by considering a total of the weights of the linear guide 363 and the multi-support 364 or in terms of cost, for example, on condition that the difference dLE between coefficients of linear expansion fulfills the inequality given above. In the first embodiment, materials for the linear guide 363 and the multi-support 364 are determined in such a manner as to fulfill this material selection requirement.

The symmetrical shape requirement will be described next. As shown in FIG. 4, the symmetrical shape requirement is to form each of the multi-support 364 and the rail 363a (slide member) into a plane symmetrical shape with respect to a vertical virtual plane VS. As indicated by dashed-dotted lines in FIG. 4, the vertical virtual plane VS mentioned herein means a vertical plane including the center 21C of the spin base 21 and parallel to the X direction. Even on the occurrence of a bimetallic phenomenon, the provision of such symmetry still makes it possible to eliminate or reduce deformation of each of the multi-support 364 and the rail 363a in the Y direction. Thus, the positions of the second contact member 32 and the third contact member 33 can be maintained relative to each other in the Y direction. As a result, it becomes possible to suppress deterioration of centering accuracy. It is certainly more preferable that the shape of the linear guide 363 including the block 363b as well as the rail 363a be a plane symmetrical shape with respect to the vertical virtual plane VS. As shown in FIG. 4, the symmetrical shape requirement is fulfilled in the first embodiment.

As described above, in the first embodiment, the X direction and the Y direction correspond to a “first horizontal direction” and a “second horizontal direction” of the present invention respectively. The motor 362 corresponds to an example of a “driver” of the present invention. The pinion gear 365a and the rack gear 365b correspond to an example of a “first power transmission member” and an example of a “second power transmission member” of the present invention respectively. The controller 9 functions as a “controller” of the present invention. The end portion 364b2 of the multi-support member 364b closer to the Y2 direction corresponds to an example of “one end portion in the second horizontal direction” of the present invention. The end portion 364b1 of the multi-support member 364b closer to the Y1 direction corresponds to an example of “the other end portion in the second horizontal direction” of the present invention.

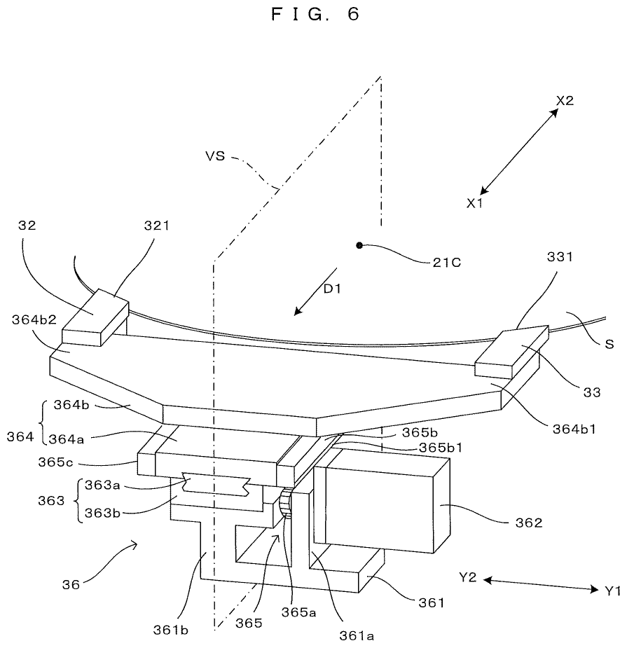

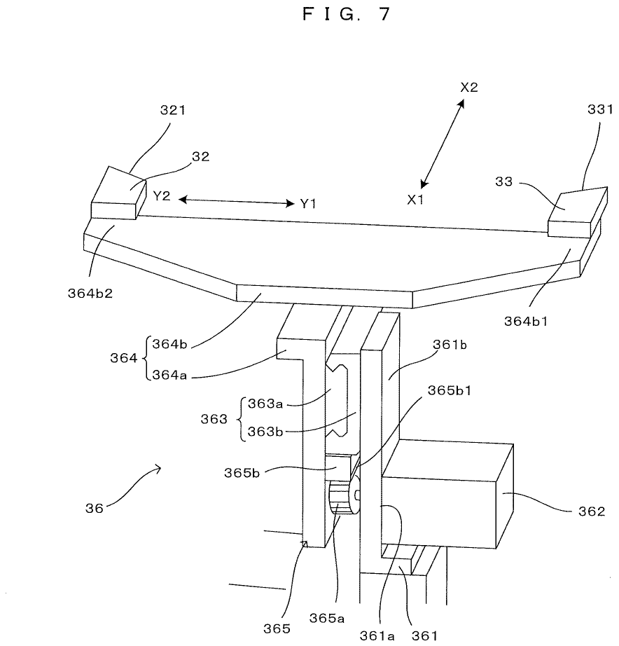

As shown in FIG. 4, in the above-described embodiment, the slide base 364a of the multi-support 364 is mounted with the rack gear 365b only on a side surface of the slide base 364a closer to the Y1 direction. As shown in FIG. 6, a side surface of the slide base 364a closer to the Y2 direction may be mounted with a dummy part 365c of the rack gear 365b having the same configuration as the rack gear 365b (second embodiment). As an example, a part same as the rack gear 365b may be used as the dummy part 365c, and this part may be mounted on the slide base 364a in a state of not forming meshing engagement with the pinion gear 365a. This provides a plane symmetrical shape with respect to the vertical virtual plane VS to a constituent element (=365b+365c) mounted on the multi-support 364 as well as to the multi-support 364 and the rail 363a (slide member), making it possible to suppress deterioration of centering accuracy more reliably.

FIG. 7 is a perspective view showing the configuration of a multi-mover provided to a third embodiment of the centering device according to the present invention. The third embodiment largely differs from the first embodiment (FIG. 4) and the second embodiment (FIG. 6) described above in that the linear guide 363 and the power transmitter 365 are arranged in the top-bottom direction, and the slide base 364a of the multi-support 364 extends in the top-bottom direction along the arrangement of the linear guide 363 and the power transmitter 365 and is coupled to the rack gear 365b and the rail 363a (slide member). These differences will be discussed mainly in the following description about the detailed configuration of the multi-mover 36.

In the third embodiment, the base member 361 is fixed to the frame (not shown in the drawings) of the substrate processing apparatus 10. At the base member 361, the linear guide base part 361b is provided over the motor base part 361a. The motor base part 361a is mounted with the motor 362 in such a posture that the rotary shaft thereof faces the slide base 364a. The linear guide base part 361b is mounted with the linear guide 363 such as an LM guide (registered trademark). The linear guide 363 includes the rail 363a extended in the X direction, and the block 363b provided in a manner slidable in the X direction along the rail 363a relative to the rail 363a. As shown in FIG. 7, in the present embodiment, the block 363b and the rail 363a are provided in a state of being interposed between the linear guide base part 361b and the slide base 364a in the order named. The block 363b is fixed to a predetermined position at a side surface of the linear guide base part 361b with a fastening fitting such as a bolt. Meanwhile, the rail 363a is coupled to the slide base 364a in a state of being movable back and forth in the X direction relative to the block 363b. Furthermore, the multi-support member 364b is mounted on an upper end of the slide base 364a. Thus, the multi-support 364 is movable back and forth integrally with the rail 363a in the X direction relative to the block 363b. When driving force generated by the motor 362 is applied to the multi-support 364 through the power transmitter 365, the second contact member 32 and the third contact member 33 move in the X direction integrally with the multi-support 364.

As shown in FIG. 7, in the third embodiment, the slide base 364a and the multi-support member 364b are independent plate members having the same composition, and form the multi-support 364 by being coupled to each other. In another case, a compact composed of the integrally-formed slide base 364a and multi-support member 364b can certainly be used as the multi-support 364.

As shown in FIG. 7, the power transmitter 365 includes the pinion gear 365a mounted on the rotary shaft of the motor 362, and the rack gear 365b provided under the linear guide 363 and mounted on the slide base 364a. The rack gear 365b has such a posture that the teeth part 365b1 aligned in the X direction faces the pinion gear 365a, and the teeth part 365b1 is in meshing engagement with the pinion gear 365a. Thus, when the motor 362 operates in response to a rotation command from the motor controller 93 provided to the controller 9, driving force generated by the motor 362 is transmitted to the multi-support 364 through the pinion gear 365a and the rack gear 365b. As a result, in response to the movement of the multi-support 364 in the X2 direction, the second contact member 32 and the third contact member 33 move in the D2 direction (FIG. 3) and the D3 direction (FIG. 3) respectively.

At the multi-mover 36 having the above-described configuration, the material selection requirement is fulfilled. Specifically, materials for forming the multi-support 364 and the rail 363a (slide member) are selected in such a manner as to fulfill the formula (4) given above. Thus, it is possible to effectively suppress deterioration of centering accuracy caused by a bimetallic phenomenon like in the first embodiment or the second embodiment.

The third embodiment employs a so-called vertically-mounted layout where the linear guide 363 and the power transmitter 365 are arranged in the top-bottom direction along the slide base 364a hanging down from the multi-support member 364b. Thus, compared to the first embodiment (FIG. 4) or the second embodiment (FIG. 6) employing a so-called horizontally-mounted layout where the slide base 364a is staked and arranged on an upper surface of the linear guide 363 in a horizontal posture with the rack gear 365b of the power transmitter 365 mounted on the side surface of the slide base 364a, the centering mechanism 3 according to the third embodiment can be reduced in size in the horizontal plane.

As described above, in the third embodiment, the slide base 364a and the multi-support member 364b correspond to an example of a “hanging member” and an example of a “horizontal support member” of the present invention.

Note that the present invention is not limited to the above embodiments and various changes other than the aforementioned ones can be made without departing from the gist of the invention. For example, while the first embodiment and the second embodiment are configured to fulfill both the material selection requirement and the symmetrical shape requirement, the first embodiment and the second embodiment may be configured to fill only one of these requirements.

If the above-described horizontally-mounted layout is employed, the single mover 35 may be configured to fulfill at least one of the material selection requirement and the symmetrical shape requirement. If the above-described vertically-mounted layout is employed, the single mover 35 may be configured to fulfill the material selection requirement. Using the single mover 35 having such a configuration makes it possible to enhance centering accuracy to a greater degree.

In the above-described embodiments, the present invention is applied to the centering device provided to the substrate processing apparatus 10 that performs the bevel etching process. Meanwhile, the centering device according to the present invention is applicable to every type of centering device provided to a substrate processing techniques that performs a process while rotating a substrate of a circular plate shape and to and every type of centering method. Also, the centering device according to the present invention may be used alone.

Although the invention has been described with reference to specific embodiments, this description is not meant to be construed in a limiting sense. Various modifications of the disclosed embodiment, as well as other embodiments of the present invention, will become apparent to persons skilled in the art upon reference to the description of the invention. It is therefore contemplated that the appended claims will cover any such modifications or embodiments as fall within the true scope of the invention.

This invention is applicable to a centering technique for aligning a center of a disk-like substrate with a center of a substrate holder while the substrate is placed on an upper surface of the substrate holder, and is applicable to substrate processing apparatuses in general for processing substrates utilizing the centering technique.

What is claimed is:

1. A centering device comprising:
a first contact member capable of contacting an end face of a disk-like substrate placed in a horizontal posture on an upper surface of a substrate holder;
a single mover configured to move the first contact member in a first horizontal direction;
a second contact member and a third contact member each capable of contacting the end face of the substrate from an opposite side to the first contact member across the substrate holder;
a multi-mover configured to move the second contact member and the third contact member integrally in the first horizontal direction while the second contact member and the third contact member surround a center of the substrate holder together with the first contact member in a plan view vertically from above; and
a controller configured to control the single mover and the multi-mover so as to determine the position of the substrate on the substrate holder in such a manner that the substrate is sandwiched by the first contact member, the second contact member, and the third contact member from the first horizontal direction and the center of the substrate is aligned with the center of the substrate holder, wherein
the multi-mover includes:
a multi-support configured to support the second contact member and the third contact member integrally;
a guide member extended in the first horizontal direction;
a slide member mounted in a manner slidable in the first horizontal direction relative to the guide member fixedly arranged at a predetermined position while the slide member is coupled to the multi-support;
a driver configured to generate driving force for moving the multi-support in the first horizontal direction; and
a power transmitter configured to transmit the driving force to the multi-support, and
with the amount of eccentricity of the substrate from the substrate holder permitted for a degree of change dTM in an ambient temperature defined as a permissible eccentricity amount AE, the multi-support and the slide member are made of materials having respective coefficients of linear expansion with a difference dLE therebetween that fulfills an inequality as follows:
$$dLE < AE / ( 0.8597 \times dTM ) .$$

2. The centering device according to claim 1, wherein
the multi-support includes:
a horizontal support member extended in a second horizontal direction perpendicular to the first horizontal direction, having one end portion in the second horizontal direction where the second contact member is supported, and having the other end portion in the second horizontal direction where the third contact member is supported; and
a hanging member hanging down from the horizontal support member,
the slide member is coupled to a side surface of the hanging member, and
the power transmitter is arranged under the slide member.

3. The centering device according to claim 1, wherein
the multi-support is stacked on and coupled to an upper surface of the slide member.

4. The centering device according to claim 3, wherein
the multi-support and the slide member each have a plane symmetrical shape with respect to a vertical virtual plane including the center of the substrate holder and parallel to the first horizontal direction.

5. The centering device according to claim 4, wherein
the power transmitter includes:
a first power transmission member mounted on the driver;
a second power transmission member configured to receive the driving force from the first power transmission member while the second power transmission member is mounted on the multi-support; and
a dummy part of the second power transmission member mounted on the multi-support in such a manner as to be plane symmetrical to the second power transmission member with respect to the vertical virtual plane.

6. The centering device according to claim 1, wherein
the multi-support and the slide member are made of the same material.

7. The centering device according to claim 6, wherein
the multi-support and the slide member are both made of stainless steel.

8. The centering device according to claim 1, wherein
the multi-support and the slide member are made of aluminum and stainless steel respectively.

9. A centering device comprising:
a first contact member capable of contacting an end face of a disk-like substrate placed in a horizontal posture on an upper surface of a substrate holder;
a single mover configured to move the first contact member in a first horizontal direction;
a second contact member and a third contact member each capable of contacting the end face of the substrate from an opposite side to the first contact member across the substrate holder;
a multi-mover configured to move the second contact member and the third contact member integrally in the first horizontal direction while the second contact member and the third contact member surround a center of the substrate holder together with the first contact member in a plan view vertically from above; and
a controller configured to control the single mover and the multi-mover so as to determine the position of the substrate on the substrate holder in such a manner that the substrate is sandwiched by the first contact member, the second contact member, and the third contact member from the first horizontal direction and the center of the substrate is aligned with the center of the substrate holder, wherein
the multi-mover includes:
a multi-support configured to support the second contact member and the third contact member integrally;
a guide member extended in the first horizontal direction;
a slide member mounted in a manner slidable in the first horizontal direction relative to the guide member fixedly arranged at a predetermined position while the multi-support is stacked on and coupled to an upper surface of the slide member;
a driver configured to generate driving force for moving the multi-support in the first horizontal direction; and
a power transmitter configured to transmit the driving force to the multi-support, and
the multi-support and the slide member each have a plane symmetrical shape with respect to a vertical virtual plane including the center of the substrate holder and parallel to the first horizontal direction.

10. The centering device according to claim 9, wherein
the power transmitter includes:
a first power transmission member mounted on the driver;
a second power transmission member configured to receive the driving force from the first power transmission member while the second power transmission member is mounted on the multi-support; and
a dummy part of the second power transmission member mounted on the multi-support in such a manner as to be plane symmetrical to the second power transmission member with respect to the vertical virtual plane.

11. A substrate processing apparatus comprising:
a substrate holder having an upper surface for supporting a substrate in a horizontal posture;
the centering device according to claim 1;
a suction unit configured to suck and hold the substrate on the substrate holder by exhausting air between the substrate positioned by the centering device and the substrate holder;
a rotation driver configured to rotate the substrate holder sucking and holding the substrate about a center of the substrate holder; and
a processing liquid supply mechanism configured to supply a processing liquid to a peripheral edge part of the substrate rotated about the center of the substrate holder integrally with the substrate holder.

12. A substrate processing apparatus comprising:
a substrate holder having an upper surface for supporting a substrate in a horizontal posture;
the centering device according to claim 8;
a suction unit configured to suck and hold the substrate on the substrate holder by exhausting air between the substrate positioned by the centering device and the substrate holder;
a rotation driver configured to rotate the substrate holder sucking and holding the substrate about a center of the substrate holder; and
a processing liquid supply mechanism configured to supply a processing liquid to a peripheral edge part of the substrate rotated about the center of the substrate holder integrally with the substrate holder.
